(19) United States
(12) Patent Application Publication
(10) Pub. No.: US 2025/0062592 A1
(43) Pub. Date: Feb. 20, 2025

(54) OPTICAL MODULE PACKAGING STRUCTURE AND METHOD OF MANUFACTURING THE SAME

(71) Applicant: PRIMAX ELECTRONICS LTD., Taipei City (TW)

(72) Inventors: CHING-HUI CHANG, Taipei City (TW); SHENG-HSIANG CHIU, Taipei City (TW)

(21) Appl. No.: 18/454,831

(22) Filed: Aug. 24, 2023

(30) Foreign Application Priority Data
Aug. 14, 2023 (TW) 112130474

(51) Int. Cl. H01S 5/0232; H01L 23/00; H01S 5/0236; H01S 5/0237; H01S 5/024; H05K 1/18; H05K 3/34

(52) U.S. Cl. CPC H01S 5/0232; H01L 24/32; H01L 24/83; H01S 5/0236; H01S 5/0237; H01S 5/02469; H05K 1/181; H05K 3/3485; H01L 24/16; H01L 24/73; H01L 2224/16225; H01L 2224/32245; H01L 2224/73253; H01L 2224/83191; H01L 2924/1426; H01S 5/183; H05K 2201/10515; H05K 2201/10757; H05K 2201/10946

(57) ABSTRACT

An optical module packaging structure is provided, which includes a circuit board, an electronic component, a lead frame and a light emitting module. The electronic component is disposed on the circuit board. The lead frame is disposed on the electronic component, in which the lead frame has a first connection portion electrically connected to the circuit board. The light emitting module is disposed on the lead frame, in which the light emitting module includes a first connection pad located at a bottom of the light emitting module, and the first connection pad is electrically connected to the circuit board through the first connection portion of the lead frame. A method of manufacturing the aforementioned optical module packaging structure is also provided.

### FIELD OF THE INVENTION

The present disclosure relates to an optical module packaging structure and a method of manufacturing the same.

### BACKGROUND OF THE INVENTION

As a size of an electronic product becomes thinner and smaller, a packaging structure inside the electronic product continues to develop toward miniaturization. Therefore, how to further reduce a volume of the packaging structure has become a technical issue in this field.

### SUMMARY OF THE INVENTION

The present disclosure provides an optical module packaging structure, which includes a circuit board, an electronic component, a lead frame and a light emitting module. The electronic component is disposed on the circuit board. The lead frame is disposed on the electronic component, in which the lead frame has a first connection portion electrically connected to the circuit board. The light emitting module is disposed on the lead frame, in which the light emitting module includes a first connection pad located at a bottom of the light emitting module, and the first connection pad is electrically connected to the circuit board through the first connection portion of the lead frame.

In some embodiments of the present disclosure, the light emitting module further includes a vertical-cavity surface-emitting laser (VCSEL).

In some embodiments of the present disclosure, the electronic component is a driver electrically connected to the circuit board, and the driver is electrically connected to the first connection pad through the circuit board and the first connection portion.

In some embodiments of the present disclosure, one end of the first connection portion is electrically connected to the circuit board through a solder, and the driver is electrically connected to the first connection pad through the circuit board, the solder and the first connection portion.

In some embodiments of the present disclosure, the optical module packaging structure further includes: an electrically conductive adhesive layer, disposed between the first connection pad and the first connection portion of the lead frame.

In some embodiments of the present disclosure, the optical module packaging structure further includes: a thermally conductive adhesive layer, disposed between the lead frame and a top of the electronic component.

In some embodiments of the present disclosure, the optical module packaging structure further includes: a heat sink, disposed between the thermally conductive adhesive layer and the top of the electronic component; and an adhesive layer, disposed between the heat sink and the top of the electronic component.

In some embodiments of the present disclosure, the lead frame further has a second connection portion separated from the first connection portion and electrically connected to the circuit board, and the light emitting module further includes a second connection pad located at the bottom of the light emitting module and separated from the first connection pad, and the second connection pad is electrically connected to the circuit board through the second connection portion of the lead frame.

In some embodiments of the present disclosure, the first connection portion has a first protrusion, and the second connection portion has a second protrusion, and the first protrusion and the second protrusion face to each other.

In some embodiments of the present disclosure, a width of the first protrusion is the same or substantially the same as a width of the second protrusion.

The present disclosure provides a method of manufacturing an optical module packaging structure, which includes: receiving a circuit board and an electronic component on the circuit board; fixing a lead frame on a bottom of a light emitting module to form a stacked structure; fixing the lead frame of the stacked structure on the electronic component; and making the lead frame electrically connect to the circuit board.

In some embodiments of the present disclosure, fixing the lead frame on the bottom of the light emitting module includes: forming an electrically conductive adhesive layer on the bottom of the light emitting module; bonding the lead frame to the electrically conductive adhesive layer; and performing a curing process to fix the lead frame on the bottom of the light emitting module through the electrically conductive adhesive layer.

In some embodiments of the present disclosure, the lead frame has a first connection portion, and the light emitting module includes a first connection pad located at the bottom of the light emitting module, and performing the curing process to fix the lead frame on the bottom of the light emitting module through the electrically conductive adhesive layer includes: fixing a portion of the first connection portion on the first connection pad through the electrically conductive adhesive layer.

In some embodiments of the present disclosure, the lead frame further has a second connection portion and an interconnection portion, and the interconnection portion is connected between the first connection portion and the second connection portion, and the light emitting module further includes a second connection pad located at the bottom of the light emitting module and separated from the first connection pad, and performing the curing process to fix the lead frame on the bottom of the light emitting module through the electrically conductive adhesive layer further includes: fixing a portion of the second connection portion on the second connection pad through the electrically conductive adhesive layer.

In some embodiments of the present disclosure, the method further includes: after performing the curing process and before fixing the lead frame of the stacked structure on the electronic component, disconnecting the interconnection portion to electrically isolate the first connection portion from the second connection portion.

In some embodiments of the present disclosure, disconnecting the interconnection portion is conducted by using a laser, and a wavelength of the laser is in a range of from 960 nm to 1,070 nm.

In some embodiments of the present disclosure, fixing the lead frame of the stacked structure on the electronic component is fixing the lead frame of the stacked structure on the electronic component through a thermally conductive adhesive layer.

In some embodiments of the present disclosure, making the lead frame electrically connect to the circuit board is conducted by using a solder jet process.

In some embodiments of the present disclosure, the light emitting module includes a vertical-cavity surface-emitting laser, and the electronic component is a driver electrically connected to the circuit board.

### BRIEF DESCRIPTION OF THE DRAWINGS

Aspects of the present disclosure are best understood from the following embodiments, read in conjunction with accompanying drawings. However, it should be understood that in accordance with common practice in the industry, various features have not necessarily been drawn to scale. Indeed, shapes of the various features may be suitably adjusted for clarity, and dimensions of the various features may be arbitrarily increased or decreased.

FIG. 1 is a perspective view of an optical module packaging structure according to an embodiment of the present invention.

FIG. 2 is a cross-sectional view of an optical module packaging structure according to an embodiment of the present invention.

FIG. 3 is a perspective view of a lead frame according to an embodiment of the present invention.

FIG. 4 is a perspective view of a light emitting module according to an embodiment of the present invention.

FIG. 5 is a cross-sectional view of an optical module packaging structure according to another embodiment of the present invention.

FIGS. 6 to 11 are perspective views of various process stages of a method of manufacturing an optical module packaging structure according to an embodiment of the present invention.

### DETAIL DESCRIPTION OF THE PREFERRED EMBODIMENT

The advantages and features of the present disclosure and the method for achieving the same will be described in more detail with reference to exemplary embodiments and accompanying drawings to make it easier to understand. However, the present disclosure can be implemented in different forms and should not be construed as being limited to the embodiments set forth herein. On the contrary, for those skilled in the art, the provided embodiments will make this disclosure more thorough, comprehensive and complete to convey the scope of the present disclosure.

The spatially relative terms in the text, such as “beneath” and “over”, are used to facilitate the description of the relative relationship between one element or feature and another element or feature in the drawings. The true meaning of the spatially relative terms includes other orientations. For example, when the drawing is flipped up and down by 180°, the relationship between the one element and the other element may change from “beneath” to “over.” The spatially relative descriptions used herein should be interpreted the same.

As mentioned in background of the invention, how to further reduce the volume of the packaging structure has become the technical issue in this field. Accordingly, the present invention provides an optical module packaging structure, which includes a circuit board, an electronic component, a lead frame and a light emitting module. Compared with a packaging structure in which a light emitting module and an electronic components are disposed in different positions, the packaging structure of the present invention that the electronic component and the light emitting module are vertically stacked occupies a smaller plane space (i.e., X/Y dimension). In another aspect, the packaging structure of the present invention that a light and thin lead frame is used as an electrical connector between the light emitting module and the circuit board can make the packaging structure of the present invention smaller and applicable to various electronic products with miniaturized sizes (e.g., AR glasses or VR glasses). In addition, the lead frame has good heat conduction effect, which can make the packaging structure of the present invention have good heat dissipation performance. Various embodiments of the optical module packaging structure of the present invention will be described in detail below.

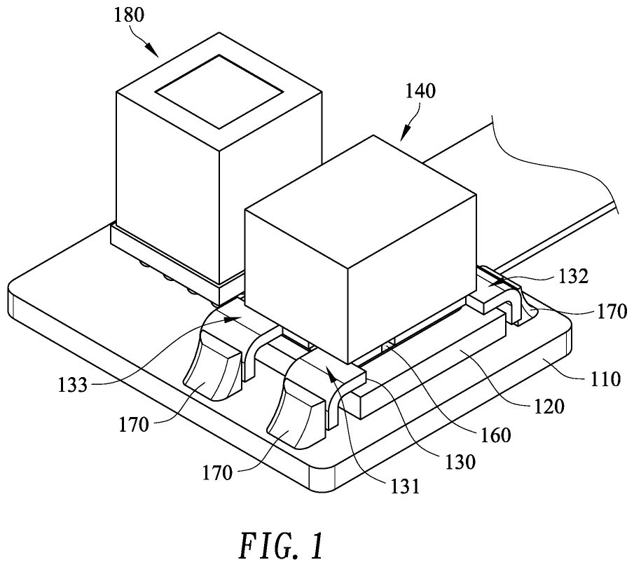

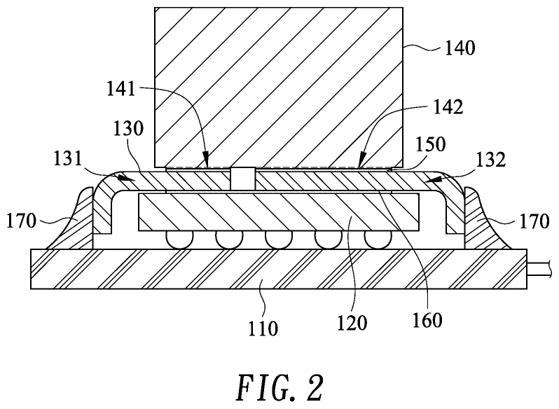

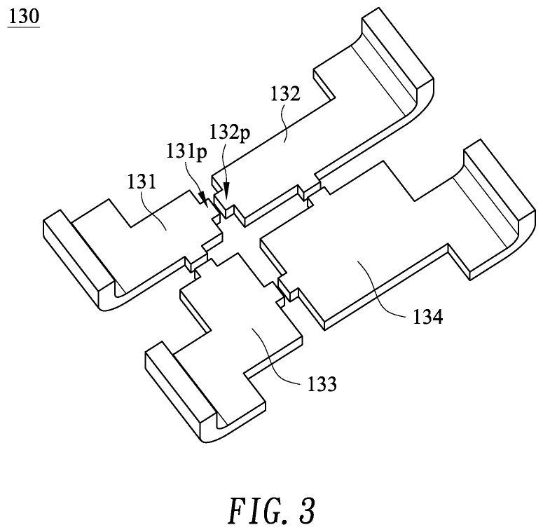

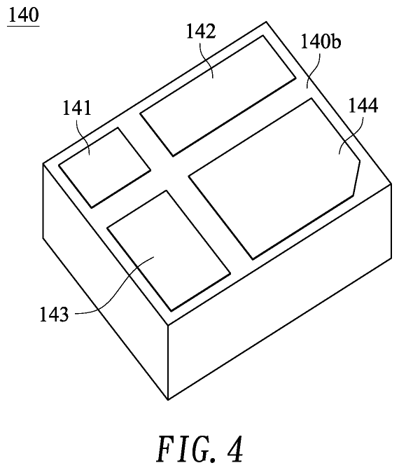

FIG. 1 is a perspective view of an optical module packaging structure according to an embodiment of the present invention. FIG. 2 is a cross-sectional view of an optical module packaging structure according to an embodiment of the present invention. FIG. 3 is a perspective view of a lead frame according to an embodiment of the present invention. FIG. 4 is a perspective view of a light emitting module according to an embodiment of the present invention. Referring to FIGS. 1 to 4, the optical module packaging structure includes a circuit board 110, an electronic component 120, a lead frame 130 and a light emitting module 140.

As shown in FIGS. 1 and 2, the electronic component 120 is disposed on the circuit board 110. In some embodiments, the electronic component 120 is electrically connected to the circuit board 110. In some embodiments, as shown in FIG. 2, the electronic component 120 is fixed on the circuit board 110 and electrically connected to the circuit board 110 (e.g., interconnect structure(s) (not shown) in the circuit board 110) through solder balls (not marked) or other suitable conductive elements. In some embodiments, the electronic component 120 is a driver (e.g., a driver IC), a passive component or another suitable electronic component.

As shown in FIGS. 1 and 2, the lead frame 130 is disposed on the electronic component 120. As shown in FIGS. 1, 2 and 3, the lead frame 130 has a first connection portion 131 electrically connected to the circuit board 110. In some embodiments, one end of the first connection portion 131 is electrically connected to the circuit board 110 through the solder 170. However, the present invention is not limited to the foregoing embodiments, and the first connection portion 131 may be electrically connected to the circuit board 110 through another conductive element.

In some embodiments, the lead frame 130 further has a second connection portion 132, which is separated from the first connection portion 131 and electrically connected to the circuit board 110. In some embodiments, as shown in FIGS. 1 and 3, the lead frame 130 has a third connection portion 133 and/or a fourth connection portion 134 in addition to the first connection portion 131 and the second connection portion 132. In some embodiments, as shown in FIG. 3, the first connection portion 131, the second connection portion 132, the third connection portion 133 and the fourth connection portion 134 are separated from each other. In some embodiments, a thickness of the lead frame 130 is less than or equal to 0.2 mm, or even less than or equal to 0.15 mm.

As shown in FIGS. 1 and 2, the light emitting module 140 is disposed on the lead frame 130. As shown in FIGS. 1, 2 and 4, the light emitting module 140 includes a first connection pad 141 located at a bottom 140b of the light emitting module 140. As shown in FIG. 2, the first connection pad 141 is electrically connected to the circuit board 110 through the first connection portion 131 of the lead frame 130.

In some embodiments, the light emitting module 140 further includes a second connection pad 142, which is located at the bottom of the light emitting module 140 and is separated from the first connection pad 141, and the second connection pad 142 is electrically connected to the circuit board 110 through the second connection portion 132 of the lead frame 130. In some embodiments, as shown in FIG. 4, the light emitting module 140 includes a third connection pad 143 and/or a fourth connection pad 144 in addition to the first connection pad 141 and the second connection pad 142. In some embodiments, as shown in FIG. 4, the first connection pad 141, the second connection pad 142, the third connection pad 143 and the fourth connection pad 144 are separated from each other. In some embodiments, the bottom 140b of the light emitting module 140 is provided with a heat dissipation substrate (e.g., a ceramic substrate), and the first connection pad 141, the second connection pad 142, the third connection pad 143 and the fourth connection pad 144 are exposed from a lower surface of the heat dissipation substrate.

In some embodiments, the light emitting module 140 further includes a vertical-cavity surface-emitting laser (VCSEL) (not shown) or another suitable light emitting element. In some embodiments, the light emitting module 140 is a packaging structure of the VCSEL. In some embodiments, the VCSEL is electrically connected to the first connection portion 131, the second connection portion 132, the third connection portion 133 and/or the fourth connection portion 134. In some embodiments, referring to FIG. 2, the electronic component 120 is a driver electrically connected to the circuit board 110, and the driver is electrically connected to the first connection pad 141 through the circuit board 110 (e.g., the interconnect structure(s) in the circuit board 110) and the first connection portion 131. In some embodiments, the driver is electrically connected to the first connection pad 141 through the circuit board 110, the solder 170 and the first connection portion 131. In some embodiments, the driver is used to stabilize a power output of the light emitting element (e.g., the VCSEL) to stabilize its emission wavelength, so as to comply with IEC60825 standard or other safety standards related to laser products.

It is worth noting that, compared to using an insulating material with a conductive through-hole structure as the electrical connector between the light emitting module 140 and the circuit board 110, in the present invention, the lead frame 130 used as the electrical connector between the light emitting module 140 and the circuit board 110 can make the plane space (i.e., the X/Y dimension) occupied by the packaging structure of the present invention smaller. In addition, the lead frame 130 can conduct heat generated by the light emitting module 140/the electronic component 120 during operation to the outside, so the packaging structure of the present invention has good heat dissipation performance.

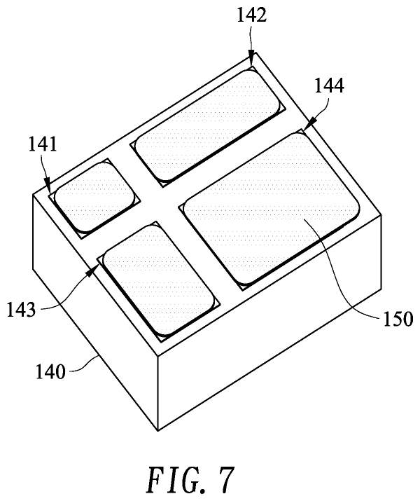

In some embodiments, as shown in FIG. 2, the optical module packaging structure further includes an electrically conductive adhesive layer 150 disposed between the first connection pad 141 and the first connection portion 131 of the lead frame 130. In some embodiments, the electrically conductive adhesive layer 150 is a patterned electrically conductive adhesive layer (referring to FIG. 7), which is also disposed between the second connection pad 142 and the second connection portion 132 of the lead frame 130, as shown in FIG. 2.

In some embodiments, as shown in FIG. 2, the optical module packaging structure further includes a thermally conductive adhesive layer 160 disposed between the lead frame 130 and a top of the electronic component 120. The heat generated by the light emitting module 140 and/or the electronic component 120 during operation can be conducted to the outside through the lead frame 130 and the thermally conductive adhesive layer 160.

In some embodiments, as shown in FIG. 1, the optical module packaging structure further includes a light receiving module 180. In some embodiments, the light receiving module 180 has a light sensor. In some embodiments, the light receiving module 180 is a camera module.

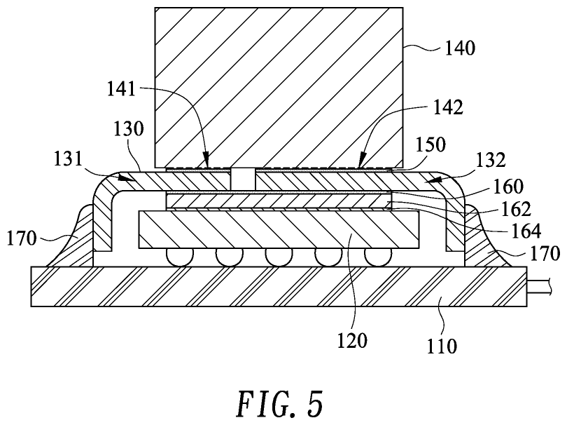

FIG. 5 is a cross-sectional view of an optical module packaging structure according to another embodiment of the present invention. The difference between FIG. 5 and FIG. 2 is that the optical module packaging structure shown in FIG. 5 further includes a heat sink 162 and an adhesive layer 164. The heat sink 162 is disposed between the thermally conductive adhesive layer 160 and the top of the electronic component 120. The adhesive layer 164 is disposed between the heat sink 162 and the top of the electronic component 120. In some embodiments, the adhesive layer 164 is another thermally conductive adhesive layer, and its material may be the same as or different from that of the thermally conductive adhesive layer 160. The heat generated by the light emitting module 140 and/or the electronic component 120 during operation can be conducted to the outside through the lead frame 130, the thermally conductive adhesive layer 160 and the heat sink 162. In some embodiments, since the heat sink 162 has a certain thickness, it can be used to adjust a height of a position of the light emitting element in the light emitting module 140, so that a field of view (FOV) of the light emitting element will not be blocked by other nearby modules (e.g., the light receiving module 180).

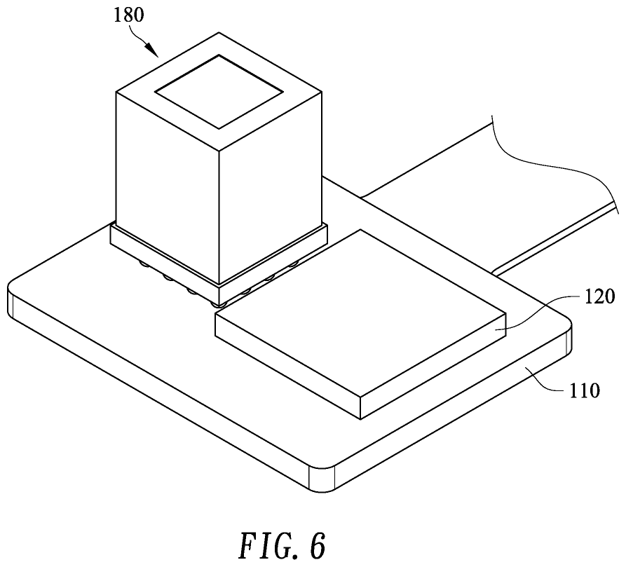

The present invention also provides a method of manufacturing an optical module packaging structure. FIGS. 6 to 11 are perspective views of various process stages of a method of manufacturing an optical module packaging structure according to an embodiment of the present invention. Each of steps of the manufacturing method of the present invention will be described in detail below.

Referring to FIG. 6, a circuit board 110 and an electronic component 120 located on the circuit board 110 are received. In some embodiments, a light receiving module 180 is also located on the circuit board 110. In some embodiments, the electronic component 120 (or the light receiving module 180) is fixed on the circuit board 110 and electrically connected to the circuit board 110 through solder balls (referring to FIG. 2) or other suitable conductive elements. In some embodiments, the electronic component 120 (or the light receiving module 180) is fixed on the circuit board 110 through surface mount technology (SMT). In some embodiments, the electronic component 120 is a driver, a passive component or another suitable electronic component.

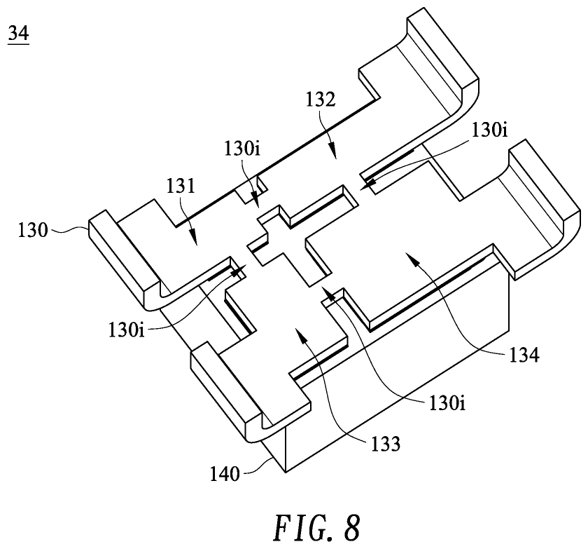

Referring to FIGS. 7 and 8, a lead frame 130 is fixed on a bottom of a light emitting module 140 to form a stacked structure 34. In some embodiments, the light emitting module 140 includes a VCSEL. In some embodiments, fixing the lead frame 130 on the bottom of the light emitting module 140 includes: forming an electrically conductive adhesive layer 150 on the bottom of the light emitting module 140, as shown in FIG. 7; bonding the lead frame 130 to the electrically conductive adhesive layer 150, as shown in FIGS. 7 and 8; and performing a curing process to fix the lead frame 130 on the bottom of the light emitting module 140 through the electrically conductive adhesive layer 150.

In some embodiments, referring to FIG. 7, when the electrically conductive adhesive layer 150 is formed on the bottom of the light emitting module 140, the electrically conductive adhesive layer 150 (or can be called a patterned conductive adhesive layer) is substantially aligned with the first connection pad 141, the second connection pad 142, the third connection pad 143 and the fourth connection pad 144 of the light emitting module 140.

In some embodiments, referring to FIG. 8, the lead frame 130 has a first connection portion 131. Performing the curing process to fix the lead frame 130 on the bottom of the light emitting module 140 through the electrically conductive adhesive layer 150 includes: fixing a portion of the first connection portion 131 on the first connection pad 141 through the electrically conductive adhesive layer 150.

In some embodiments, referring to FIG. 8, the lead frame 130 further has a second connection portion 132 and an interconnection portion 130i, and the interconnection portion 130i is connected between the first connection portion 131 and the second connection portion 132. Performing the curing process to fix the lead frame 130 on the bottom of the light emitting module 140 through the electrically conductive adhesive layer 150 further includes: fixing a portion of the second connection portion 132 on the second connection pad 142 through the electrically conductive adhesive layer 150.

In some embodiments, referring to FIG. 8, the lead frame 130 further has a third connection pad 143 and/or a fourth connection pad 144. In some embodiments, adjacent two of the first connection pad 141, the second connection pad 142, the third connection pad 143 and the fourth connection pad 144 are interconnected through the interconnection portion 130i.

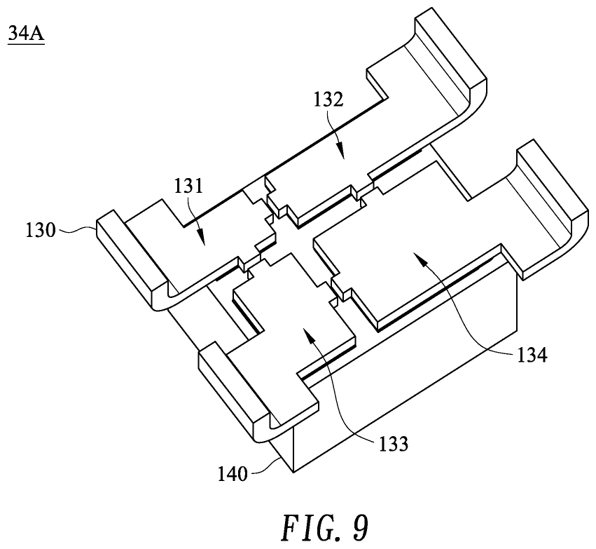

In some embodiments, referring to FIGS. 8 and 9, the method further includes: after performing the curing process and before fixing the lead frame of the stacked structure on the electronic component (referring to FIGS. 9 to 11, which will be described in detail later), disconnecting the interconnection portion 130i to electrically isolate the first connection portion 131 from the second connection portion 132. In some embodiments, all of the interconnection portions 130i shown in FIG. 8 are disconnected to separate the first connection pad 141, the second connection pad 142, the third connection pad 143 and the fourth connection pad 144 from each other. In some embodiments, a laser with a specific wavelength range is used to disconnect the interconnection portions 130i. Specifically, the interconnection portions 130i effectively absorb thermal energy of the laser and are melted and disconnected, and the laser does not damage the bottom of the light emitting module 140. In some embodiments, the wavelength of the aforementioned laser is in a range of from 960 nm and 1,070 nm.

However, the present invention is not limited to the above-mentioned embodiments. In other embodiments, the lead frame 130 (having the first connection pad 141, the second connection pad 142, the third connection pad 143, and the fourth connection pad 144 separated from each other) shown in FIG. 9 may be directly fixed on the bottom of the light emitting module 140 to form a stacked structure 34A.

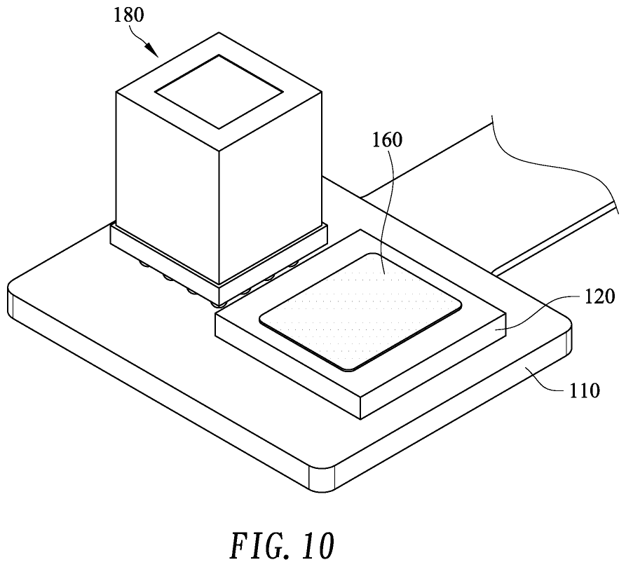

Referring to FIGS. 9 to 11, the lead frame 130 of the stacked structure 34A is fixed on the electronic component 120. In some embodiments, fixing the lead frame 130 of the stacked structure 34A on the electronic component 120 is fixing the lead frame 130 of the stacked structure 34A on the electronic component 120 through a thermally conductive adhesive layer 160. In some embodiments, fixing the lead frame 130 of the stacked structure 34A on the electronic component 120 includes: forming the thermally conductive adhesive layer 160 on the electronic component 120, as shown in FIG. 10; bonding the lead frame 130 of the stacked structure 34A to the thermally conductive adhesive layer 160, as shown in FIGS. 9 to 11; and performing a curing process to fix the lead frame 130 of the stacked structure 34A on the electronic component 120 through the thermally conductive adhesive layer 160.

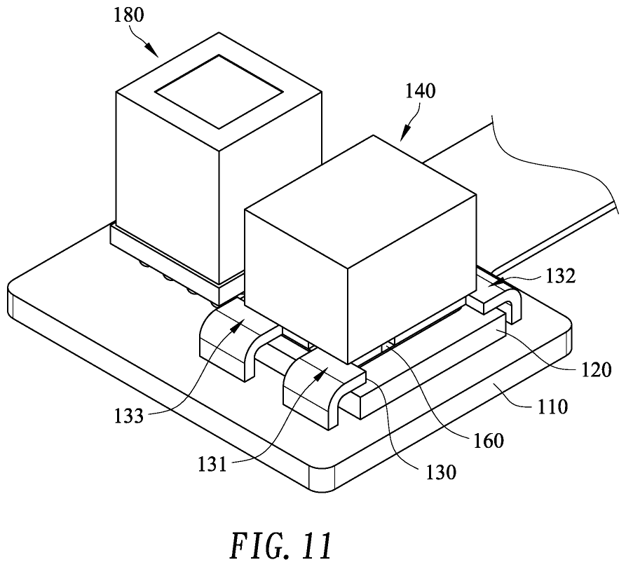

Referring to FIGS. 11 and 1, the lead frame 130 is electrically connected to the circuit board 110. In some embodiments, making the lead frame 130 electrically connect to the circuit board 110 is conducted by using a solder jet process to form solder(s) 170 electrically connected between the lead frame 130 and the circuit board.

However, the above are only the preferred embodiments of the present disclosure, and should not be used to limit the scope of implementation of the present disclosure, that is, simple equivalent changes and modifications made in accordance with claims and description of the present disclosure are still within the scope of the present disclosure. In addition, any embodiment of the present disclosure or claim does not need to achieve all the objectives or advantages disclosed in the present disclosure. In addition, the abstract and the title are not intended to limit the scope of claims of the present disclosure.

What is claimed is:

1. An optical module packaging structure, comprising:
a circuit board;
an electronic component, disposed on the circuit board;
a lead frame, disposed on the electronic component, wherein the lead frame has a first connection portion electrically connected to the circuit board; and
a light emitting module, disposed on the lead frame, wherein the light emitting module comprises a first connection pad located at a bottom of the light emitting module, and the first connection pad is electrically connected to the circuit board through the first connection portion of the lead frame.

2. The optical module packaging structure of claim 1, wherein the light emitting module further comprises a vertical-cavity surface-emitting laser (VCSEL).

3. The optical module packaging structure of claim 1, wherein the electronic component is a driver electrically connected to the circuit board, and the driver is electrically connected to the first connection pad through the circuit board and the first connection portion.

4. The optical module packaging structure of claim 3, wherein one end of the first connection portion is electrically connected to the circuit board through a solder, and the driver is electrically connected to the first connection pad through the circuit board, the solder and the first connection portion.

5. The optical module packaging structure of claim 1, further comprising:
an electrically conductive adhesive layer, disposed between the first connection pad and the first connection portion of the lead frame.

6. The optical module packaging structure of claim 1, further comprising:
a thermally conductive adhesive layer, disposed between the lead frame and a top of the electronic component.

7. The optical module packaging structure of claim 6, further comprising:
a heat sink, disposed between the thermally conductive adhesive layer and the top of the electronic component; and
an adhesive layer, disposed between the heat sink and the top of the electronic component.

8. The optical module packaging structure of claim 1, wherein the lead frame further has a second connection portion separated from the first connection portion and electrically connected to the circuit board, and the light emitting module further comprises a second connection pad located at the bottom of the light emitting module and separated from the first connection pad, and the second connection pad is electrically connected to the circuit board through the second connection portion of the lead frame.

9. The optical module packaging structure of claim 8, wherein the first connection portion has a first protrusion, and the second connection portion has a second protrusion, and the first protrusion and the second protrusion face to each other.

10. The optical module packaging structure of claim 9, wherein a width of the first protrusion is the same or substantially the same as a width of the second protrusion.

11. A method of manufacturing an optical module packaging structure, comprising:
receiving a circuit board and an electronic component on the circuit board;
fixing a lead frame on a bottom of a light emitting module to form a stacked structure;
fixing the lead frame of the stacked structure on the electronic component; and
making the lead frame electrically connect to the circuit board.

12. The method of claim 11, wherein fixing the lead frame on the bottom of the light emitting module comprises:
forming an electrically conductive adhesive layer on the bottom of the light emitting module;
bonding the lead frame to the electrically conductive adhesive layer; and
performing a curing process to fix the lead frame on the bottom of the light emitting module through the electrically conductive adhesive layer.

13. The method of claim 12, wherein the lead frame has a first connection portion, and the light emitting module comprises a first connection pad located at the bottom of the light emitting module, and performing the curing process to fix the lead frame on the bottom of the light emitting module through the electrically conductive adhesive layer comprises:
fixing a portion of the first connection portion on the first connection pad through the electrically conductive adhesive layer.

14. The method of claim 13, wherein the lead frame further has a second connection portion and an interconnection portion, and the interconnection portion is connected between the first connection portion and the second connection portion, and the light emitting module further comprises a second connection pad located at the bottom of the light emitting module and separated from the first connection pad, and performing the curing process to fix the lead frame on the bottom of the light emitting module through the electrically conductive adhesive layer further comprises:
fixing a portion of the second connection portion on the second connection pad through the electrically conductive adhesive layer.

15. The method of claim 14, further comprising:
after performing the curing process and before fixing the lead frame of the stacked structure on the electronic component, disconnecting the interconnection portion to electrically isolate the first connection portion from the second connection portion.

16. The method of claim 15, wherein disconnecting the interconnection portion is conducted by using a laser, and a wavelength of the laser is in a range of from 960 nm to 1,070 nm.

17. The method of claim 11, wherein fixing the lead frame of the stacked structure on the electronic component is fixing the lead frame of the stacked structure on the electronic component through a thermally conductive adhesive layer.

18. The method of claim 11, wherein making the lead frame electrically connect to the circuit board is conducted by using a solder jet process.

19. The method of claim 11, wherein the light emitting module comprises a vertical-cavity surface-emitting laser, and the electronic component is a driver electrically connected to the circuit board.
